(19) United States
(12) Patent Application Publication
(10) Pub. No.: US 2015/0014765 A1
(43) Pub. Date: Jan. 15, 2015

(54) RADIATION RESISTANT CMOS DEVICE AND METHOD FOR FABRICATING THE SAME

(71) Applicant: PEKING UNIVERSITY, Beijing (CN)

(72) Inventors: Ru Huang, Beijing (CN); Fei Tan, Beijing (CN); Xia An, Beijing (CN); Weikang Wu, Beijing (CN); Liangxi Huang, Beijing (CN)

(73) Assignee: PEKING UNIVERSITY, Beijing (CN)

(21) Appl. No.: 14/377,838

(22) PCT Filed: Jun. 5, 2013
(86) PCT No.: PCT/CN2013/076745

§ 371 Date: Aug. 8, 2014

(30) Foreign Application Priority Data
Aug. 14, 2012 (CN) 201210289276.7

(51) Int. Cl. H01L 27/092; H01L 21/8238; H01L 29/66; H01L 29/778

(52) U.S. Cl. CPC H01L 27/092; H01L 29/7788; H01L 21/8238; H01L 29/66666
USPC 257/329; 438/212

(57) ABSTRACT

A radiation resistant CMOS device and a method for fabricating the same. The CMOS device includes a substrate, a source region, a drain region and a vertical channel on the substrate. A first dielectric protection region is inserted into the vertical channel at the center of the vertical channel to divide the vertical channel into two parts and has a height equal to the length of the vertical channel. The edge of the first dielectric protection region is 20-100 nm from an outer side of the channel, with a central axis of an silicon platform for an active region as the center. A second dielectric protection region is disposed under the source or drain region, with a length equal to the length of the source or drain region and a height of 10-50 nm. The dielectric protection regions effectively block paths for the source and drain regions collecting charges.

### CROSS REFERENCE OF RELATED APPLICATIONS

The present application claims priority of Chinese application No. 201210289276.7, filed on Aug. 14, 2012, which is incorporated herein by reference in its entirety.

### FIELD OF THE INVENTION

The present invention refers to CMOS integrated circuit technologies, and in particular, refers to a radiation resistant CMOS device and a method for fabricating the same.

### BACKGROUND OF THE INVENTION

Rapid development and wide application of information technologies have changed conventional ways of production, business, management and life, and have brought profound influences on various aspects of human society. With the development of science and technology, especially space technology, nuclear power and nuclear weapon, the relationship between a nuclear radiation environment and an electrical technology are increasingly intimate. In order to meet the requirement for radiation resistance performance of the integrated circuits needed by the development of aerospace technology, certain key integrated circuits in satellites and spacecrafts need to use radiation hardening devices. Impelled by the development of aerospace technology and improvement of universal exploration, researchers are engaged in deeply researching the influence of the natural space radiation environment on the performance of the integrated circuits, and seeking a feasible hardening method.

Current researches on a radiation effect of CMOS integrated circuits are mainly focused on a total dose effect and a single event effect. At present, a mainstream CMOS integrated circuit is comprised of conventional bulk silicon devices. In the conventional bulk silicon device, as a gate oxide layer further shrinks, charges generated in the gate oxide layer by a radiation resource have negligible influence on the performance of the device. However, charges trapped in STI regions may turn-on a parasite transistor, which may affect a normal operation of the device. Moreover, due to a large charge collection region in the silicon substrate, the particles incident on sensitive nodes of the conventional bulk silicon device may cause severe single event effects, causing abnormal variation or damage of logic states of the device. Furthermore, as a size of the device shrinks, the interval between conventional bulk silicon devices is increasingly reduced. The incidence of high energy particles may induce a plurality of planar bulk silicon devices to collect charges simultaneously, that is, a charge sharing effect. The charge sharing effect may cause several nodes of the integrated circuit to toggle simultaneously, increasing a toggling cross-section and reducing an energy threshold required by the toggling. In addition, the charge sharing effect may bring in failure of the radiation hardening technology at device level and circuit level, such as a protection ring.

In order to improve the radiation resistance performance of the conventional bulk silicon device, some new device structures are gradually proposed and developed. However, generally these new device structures can only achieve a single radiation resistance target, rather than targets of resisting a total dose radiation and a single event radiation. Meanwhile, the charge sharing effect due to the small size is not considered as well. Therefore, it is useful to research a new radiation resistance device which resists the total dose radiation as well as the single event radiation while suppressing the charge sharing effect.

### SUMMARY OF THE INVENTION

An object of the present invention is to overcome the problems existing in the prior arts, and to provide a new vertical channel CMOS device which resists a total dose radiation as well as a single event radiation in a radiation environment, while suppressing a charge sharing effect due to a decreased interval between devices.

A CMOS device of the present invention comprises a substrate, a source region, a drain region and a vertical channel on the substrate. The source region is disposed above the vertical channel, and the drain region is disposed at both sides of the vertical channel on the substrate. Alternatively, the drain region is disposed above the vertical channel, and the source region is disposed at both sides of the vertical channel on the substrate. A gate electrode and a gate sidewall are disposed at both sides of the vertical channel. The CMOS device is characterized in that, a first dielectric protection region is inserted into the vertical channel. The first dielectric protection region is located in the center of the vertical channel to divide the vertical channel into two parts. A height of the first dielectric protection region is equal to a length of the vertical channel. An edge of the first dielectric protection region has a distance of 20-100 nm to an outer side of the channel, with a central axis of a silicon platform for an active region as the center. The CMOS device is also characterized in that, a second dielectric protection region is disposed under the source region or the drain region on the substrate. A length of the second dielectric protection region is equal to a length of the source region or the drain region. A height of the second dielectric protection region is 10-50 nm.

In a case of an NMOS device, the dielectric protection regions are formed of material prone to electron trapping, such as silicon nitride, or the like. In a case of a PMOS device, the dielectric protection regions are formed of material prone to hole trapping, such as silicon dioxide, or the like.

A method for fabricating a new vertical channel CMOS device based on a bulk silicon substrate includes following steps:

1) Preparing a semiconductor substrate;

2) Forming a silicon dioxide thin layer on the substrate through a thermal oxidation process, and then depositing a silicon nitride layer and a silicon dioxide layer; performing a photolithography process and etching the silicon dioxide layer and the silicon nitride layer and then corroding the silicon dioxide thin layer, so that a small step exists between the silicon dioxide layer on top and the silicon nitride layer after etching; etching the semiconductor substrate to form a semiconductor platform;

3) Forming a silicon dioxide thin layer again through a thermal oxidation process, and depositing a silicon nitride layer and a silicon dioxide layer; after an etch process, performing a local field oxidation process to form an isolation region of the device;

4) Depositing a silicon dioxide layer as a buffer layer, and performing an ion implantation process for several times under various implantation energies so that an ion concentration is uniformly distributed in the channel;

5) Depositing a silicon nitride layer and a silicon dioxide layer, and performing an etching process to the semiconductor platform for the active region for the second time, by using the silicon nitride layer and the silicon dioxide layer as a hard mask;

6) Depositing a material for a dielectric protection region, wherein in a case of an NMOS device, the dielectric protection region is formed of a material prone to electron trapping, such as silicon nitride or the like, while in a case of a PMOS device, the dielectric protection region is formed of a material prone to hole trapping, such as silicon dioxide or the like; performing a planarization process and then an etching process to form the dielectric protection region;

7) Performing a clean process, and then depositing a polysilicon layer and performing a planarization process.

8) Performing an etching process to the semiconductor platform for the active region for the third time, and performing an ion implantation process to form a source region and a drain region of the device.

9) Forming a silicon dioxide layer through a thermal oxidation process and depositing a polysilicon layer; performing an ion implantation process and then a photolithography process to define a gate line, and forming a polysilicon gate electrode and a gate sidewall by performing an etching process.

The advantages of the present invention are described as follow.

1) In the radiation environment, if high energy particles are incident on the source region (or the drain region) on top or the drain region (or the source drain) at bottom, the existence of the dielectric protection regions in the semiconductor platform effectively blocks paths for the source and drain regions collecting charges, thereby the single event characteristic of the device is improved.

2) Since the channel and the isolation oxide layer are isolated with each other, even though the isolation oxide layer traps sufficient charges, a parasite transistor is not generated in the vertical channel, and thus the total dose characteristic of the device is improved.

3) The dielectric layers disposed under the source region and the drain region can effectively block the diffusing of electrons and the holes generated by ionization of the high energy particles. Moreover, if the drain region is disposed on top and the source region is disposed at bottom when the device is operated normally, the electrons and holes generated by the charged high energy particles passing through the drain region (a sensitive node when the device is operated normally) are to be collected by a drain region of an adjacent device, in need of passing through one STI region and two source regions, and in this diffusion process the electrons and holes are dramatically combined, thereby the charge sharing effect under the single event can be improved.

### BRIEF DESCRIPTION OF THE DRAWINGS

FIG. 1 is a cross sectional view of a CMOS device proposed by the present invention; and

FIGS. 2(a)-2(q) are schematic diagrams illustrating a flow of a method for fabricating a CMOS device of the present invention.

### DETAILED DESCRIPTION OF THE EMBODIMENTS

Hereinafter, an embodiment of the present invention will be described in detail through attached drawings by taking an example of an NMOS, in which a material for a dielectric protection region is silicon nitride.

1) Preparation of a substrate: a P-type (100) silicon substrate 1 is prepared;

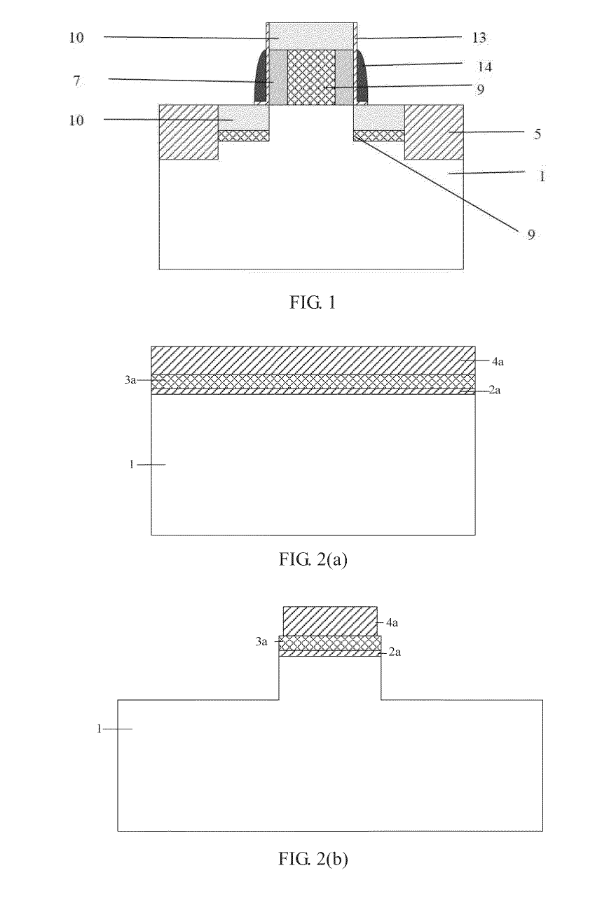

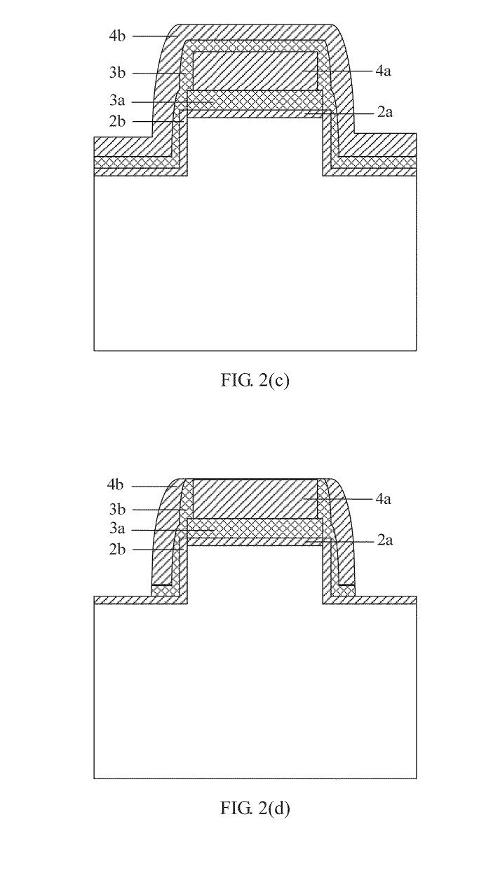

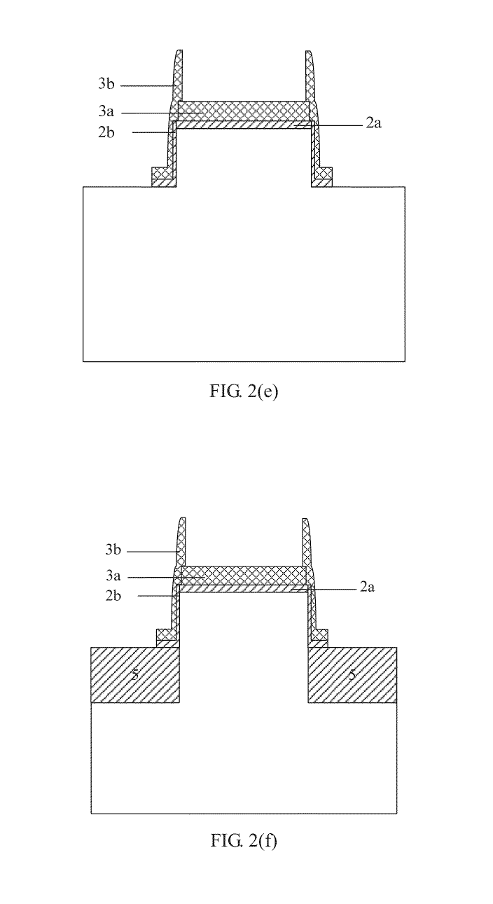

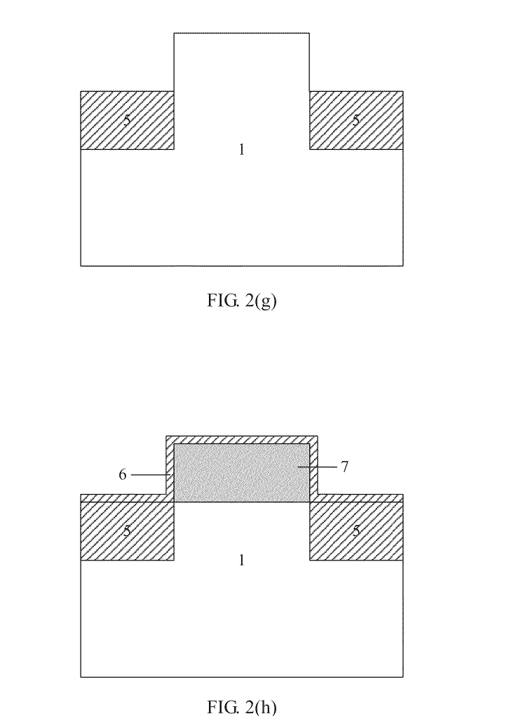

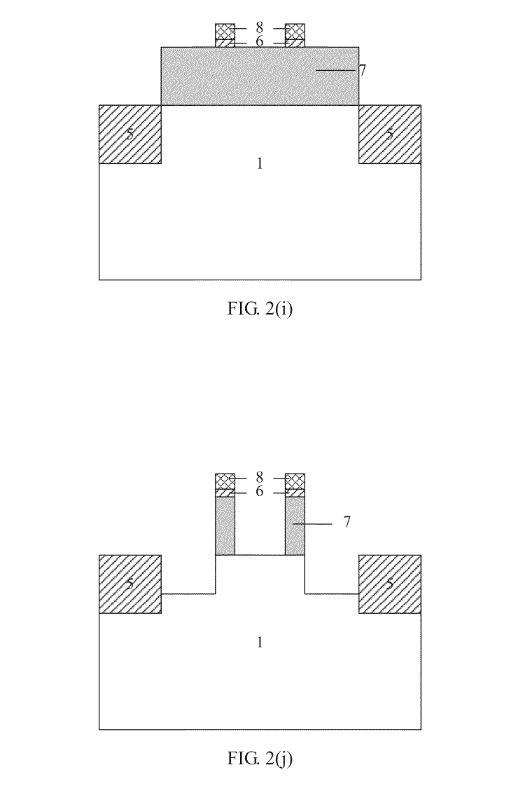

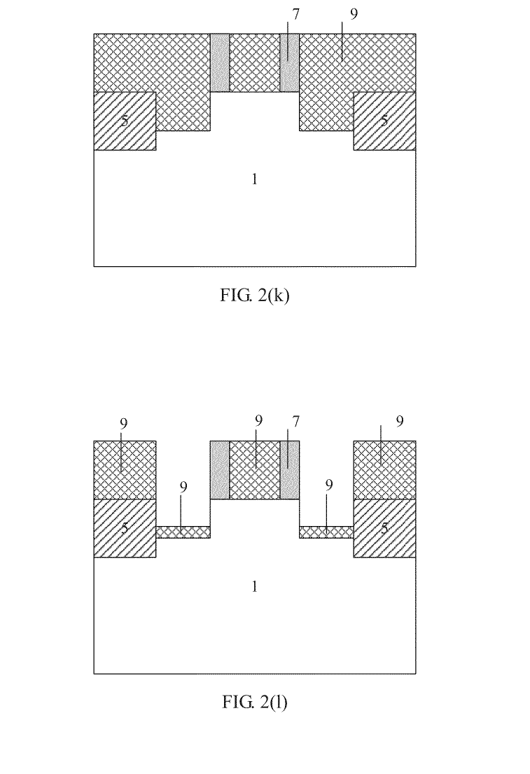

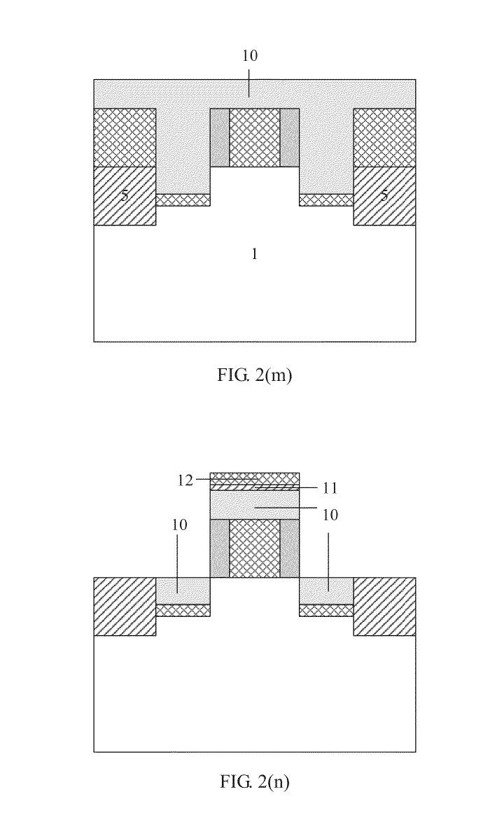

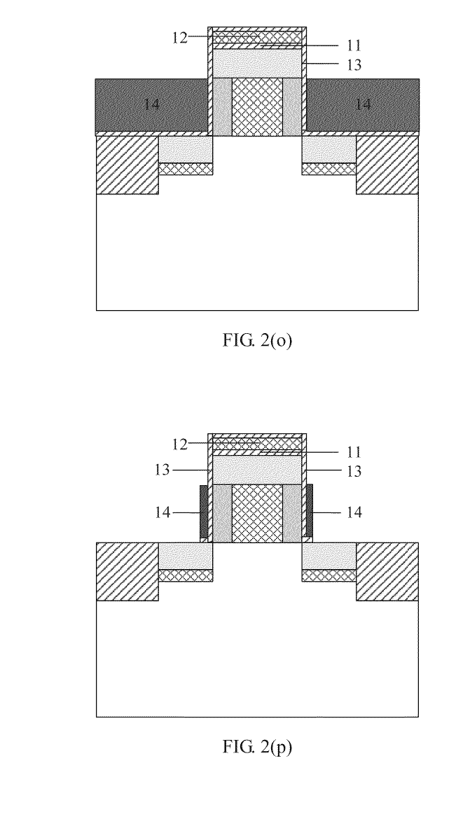

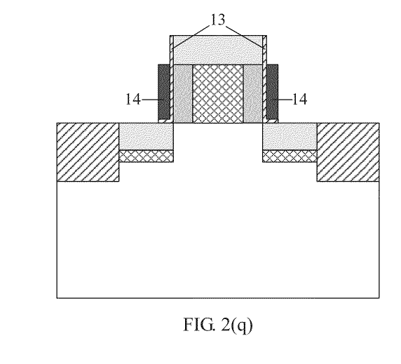

2) Etching of a silicon platform for an active region: as shown in FIG. 2(a), a silicon dioxide thin layer 2a is formed on the substrate through a thermal oxidation process, a silicon nitride layer 3a is deposited through a low pressure chemical vapor deposition (LPCVD), and then a silicon dioxide layer 4a is deposited through an LPCVD; as shown in FIG. 2(b), a photolithography process is performed, and then the silicon dioxide layer 4a is etched by a reactive ion etching (RIE) process, the silicon nitride layer 3a is etched by a RIE process and the silicon dioxide layer 2a is corroded by hydrofluoric acid, so that the silicon dioxide layer 4a and the silicon nitride layer 3a have a small step disposed therebetween after etching, and then the silicon substrate 1 is etched through an inductively coupled plasma etching (ICP) process to form the silicon platform for the active region;

3) Formation of an isolation region of the device: as shown in FIG. 2(c), a further silicon dioxide thin layer 2b is formed through a thermal oxidation process, a further silicon nitride layer 3b is deposited through an LPCVD, and then a silicon dioxide layer 4b is formed through an LPCVD; as shown in FIG. 2(d), the silicon dioxide layer 4b is etched through a RIE process, and the silicon nitride layer 3b in an field region is etched through a RIE process; as shown in FIG. 2(e), the deposited silicon dioxide layers 4a, 4b and 2b are corroded, so that both of a platform surface and sidewalls of the silicon platform are completely protected by the silicon nitride layers; as shown in FIG. 2(f), a local field oxidation process is performed to form an isolation region 5; as shown in FIG. 2(g), the silicon nitride layers 3a and 3b and the silicon dioxide layers 2a and 2b are corroded;

4) Impurity implantation of a channel: as shown in FIG. 2(h), a silicon dioxide layer 6 is deposited as a buffer layer through an LPCVD, and P-type impurities are implanted;

5) Etching of the silicon platform for the active region for the second time: as shown in FIG. 2(i), a silicon nitride layer 8 is deposited through an LPCVD, a photolithography process is performed to define a pattern of a silicon platform, and then the silicon dioxide layer 6 and the silicon nitride layer 8 are etched through a RIE process; as shown in FIG. 2(j), the silicon 1 and 7 are etched by using the silicon nitride layer 8 and silicon dioxide layer 6 as a hard mask through an ICP process;

6) Formation of a block layer: as shown in FIG. 2(k), a silicon nitride layer 9 is deposited through an LPCVD and then is subjected to a chemical mechanism polish (CMP) process; as shown in FIG. 2(l), a pattern of a source (or a drain) region at bottom is defined through a photolithography process, and then the silicon nitride layer 9 is etched through a RIE process;

7) Formation of polysilicon for the source and drain regions: as shown in FIG. 2(m), a clean process is performed, and a polysilicon layer 10 is deposited through an LPCVD and then subjected to a chemical mechanism polish (CMP) process;

8) Formation of the source and drain regions: as shown in FIG. 2(n), the silicon platform for the active region is etched for the third time, during which a silicon dioxide layer 11 is deposited through an LPCVD and a silicon nitride layer 12 is deposited through an LPCVD; a pattern of a silicon platform is defined by a photolithography process and the silicon dioxide layer 11 and the silicon nitride 12 are etched through a RIE process; the polysilicon layer 10 and the silicon nitride layer 9 are etched through an ICP process by using the silicon dioxide layer 11 and silicon nitride layer 12 as a barrier layer; N-type impurities are implanted;

9) Formation of a gate electrode and a gate sidewall: as shown in FIG. 2(o), a silicon dioxide layer 13 is formed through a thermal oxidation process, and a polysilicon layer 14 is deposited through an LPCVD; as shown in FIG. 2(p), a gate line is defined through a photolithography process, and the polysilicon layer 14 and the silicon dioxide layer 13 are etched so that a polysilicon gate electrode 14 and a gate sidewall 13 are formed; as shown in FIG. 2(q), the silicon dioxide layer 11, the silicon nitride layer 12 and the silicon dioxide layer 13 above the source or drain region on top of the silicon platform are removed.

It is noted that the embodiment is disclosed for the purpose of further understanding the present invention. However, those skilled in the art will appreciate that various substitutions and modifications are possible without departing from the spirit and the scope of the present invention and the appended claims. Therefore, the present invention should not be limited to the content disclosed by the embodiment, but based on the scope defined by the claims.

1. A CMOS device, comprising;
a substrate,
a source region,
a drain region and
a vertical channel on the substrate,
wherein
the source region is disposed above the vertical channel and the drain region is disposed at both sides of the vertical channel on the substrate, or the drain region is disposed above the vertical channel and the source region is disposed at both sides of the vertical channel on the substrate,
a gate electrode and a gate sidewall are disposed at both sides of the vertical channel,
a first dielectric protection region is inserted into the vertical channel, the first dielectric protection region being located in the center of the vertical channel to divide the vertical channel into two parts, a height of the first dielectric protection region being equal to a length of the vertical channel, and an edge of the first dielectric protection region having a distance of 20-100 nm to an outer side of the channel, with a central axis of a silicon platform for an active region as the center; and
a second dielectric protection region is disposed under the source region or the drain region on the substrate, a length of the second dielectric protection region being equal to a length of the source region or the drain region, and a height of the second dielectric protection region being 10-50 nm.

2. The CMOS device of claim 1, wherein in a case of an NMOS device, the dielectric protection regions are formed of material prone to electron trapping; in a case of a PMOS device, the dielectric protection regions are formed of material prone to hole trapping.

3. A method for fabricating the CMOS device of claim 1, comprising following steps:
1) preparing a semiconductor substrate;
2) forming a first silicon dioxide layer on the substrate through a thermal oxidation process and depositing a first silicon nitride layer and a second silicon dioxide layer; performing a photolithography process and etching the second silicon dioxide layer and the first silicon nitride layer and then corroding the first silicon dioxide layer, so that a small step exists between the second silicon dioxide layer and the first silicon nitride layer after etching; etching the semiconductor substrate to form a semiconductor platform;
3) forming a third silicon dioxide layer through a thermal oxidation process and depositing a second silicon nitride layer and a fourth silicon dioxide layer; performing an etching process and a local field oxidation process to form an isolation region of the device;
4) depositing a fifth silicon dioxide layer as a buffer layer and performing an ion implantation process, so that an ion concentration is uniformly distributed in a channel;
5) depositing a third silicon nitride layer and a sixth silicon dioxide layer, and then performing an etching process to the semiconductor platform for an active region for the second time, by using the third silicon nitride layer and the sixth silicon dioxide layer as a hard mask;
6) depositing a material for a dielectric protection region and performing an etching process;
7) depositing a first polysilicon layer and performing a planarization process;
8) performing an etching process to the semiconductor platform for the active region for the third time, and performing an ion implantation process to form a source region and a drain region of the device; and
9) forming a seventh silicon dioxide layer through a thermal oxidation process and depositing a second polysilicon layer; performing an ion implantation process and then a photolithography process to define a gate line, and forming a polysilicon gate electrode and a gate sidewall by performing an etching process.
